(19) United States
(12) Patent Application Publication
(10) Pub. No.: US 2022/0415700 A1
(43) Pub. Date: Dec. 29, 2022

(54) SUBSTRATE PROCESSING APPARATUS, SUBSTRATE MOUNTING TABLE COVER, METHOD OF MANUFACTURING SEMICONDUCTOR DEVICE AND NON-TRANSITORY COMPUTER READABLE RECORDING MEDIUM

(71) Applicant: Kokusai Electric Corporation, Tokyo (JP)

(72) Inventors: Takayuki SATO, Toyama-shi (JP); Masaki MUROBAYASHI, Toyama-shi (JP); Yuichiro TAKESHIMA, Toyama-shi (JP); Tomokazu WAKUI, Toyama-shi (JP)

(73) Assignee: Kokusai Electric Corporation, Tokyo (JP)

(21) Appl. No.: 17/903,499

(22) Filed: Sep. 6, 2022

Related U.S. Application Data
(63) Continuation of application No. PCT/JP2021/011528, filed on Mar. 19, 2021.

(30) Foreign Application Priority Data
Mar. 25, 2020 (JP) 2020-055165

(51) Int. Cl. H01L 21/687; H01L 21/67; H01J 37/32

(52) U.S. Cl. CPC H01L 21/68735; H01L 21/67115; H01J 37/3244

(57) ABSTRACT

According to one aspect of the technique of the present disclosure, there is provided a substrate processing apparatus including: a process chamber in which a substrate is accommodated; a substrate mounting table provided in the process chamber and heated by a heater; and a substrate mounting table cover arranged on an upper surface of the substrate mounting table and configured such that the substrate is placed on an upper surface of the substrate mounting table cover, wherein the substrate mounting table cover is made of silicon carbide and is provided with a silicon oxide layer of a first thickness at least on the upper surface of the substrate mounting table cover where the substrate is placed.

### CROSS-REFERENCE TO RELATED APPLICATION

This application is a bypass continuation application of PCT International Application No. PCT/JP2021/011528, filed on Mar. 19, 2021, in the WIPO, the international application being based upon and claiming the benefit of priority from Japanese Patent Application No. 2020-055165, filed on Mar. 25, 2020, in the Japanese Patent Office, the entire contents of which are hereby incorporated by reference.

### BACKGROUND

### 1. Field

The present disclosure relates to a substrate processing apparatus, a substrate mounting table cover, a method of manufacturing semiconductor device and a non-transitory computer-readable recording medium.

### 2. Related Art

When forming a circuit pattern of a semiconductor device such as a flash memory, a step of performing a predetermined process such as an oxidation process and a nitridation process on a substrate may be performed as a part of a manufacturing process of the semiconductor device. For example, according to some related arts, a surface of a pattern formed on the substrate is modified by using a plasma-excited process gas.

In a process chamber in which the substrate is processed, a substrate mounting table cover may be placed on a substrate mounting table, and the substrate to be processed may be placed on an upper surface of the substrate mounting table cover or the like to perform a substrate processing. However, in the substrate processing, when a substrate processing apparatus is used for a long period of time, an oxide layer may be formed not only on the substrate to be processed but also on a surface of a component in the process chamber such as the substrate mounting table cover by a diffusion reaction. As the oxide layer is formed on the surface of each component as described above, an emissivity on the surface thereof may change, and as a result, a processing result with respect to the substrate may be affected.

### SUMMARY

According to the present disclosure, there is provided a technique capable of suppressing a fluctuation in a substrate processing result due to a surface oxidation of a component in a process chamber accompanying an operation of a substrate processing apparatus.

According to one or more embodiments of the present disclosure, there is provided a technique related to a substrate processing apparatus including: a process chamber in which a substrate is accommodated; a substrate mounting table provided in the process chamber and heated by a heater; and a substrate mounting table cover arranged on an upper surface of the substrate mounting table and configured such that the substrate is placed on an upper surface of the substrate mounting table cover, wherein the substrate mounting table cover is made of silicon carbide and is provided with a silicon oxide layer of a first thickness at least on the upper surface of the substrate mounting table cover where the substrate is placed.

### BRIEF DESCRIPTION OF THE DRAWINGS

FIG. 1 is a diagram schematically illustrating a cross-section of a substrate processing apparatus according to one or more embodiments of the present disclosure.

FIG. 2 is a block diagram schematically illustrating a configuration of a controller (control structure) and related components of the substrate processing apparatus according to the embodiments of the present disclosure.

FIG. 3 is a flow chart schematically illustrating a substrate processing according to the embodiments of the present disclosure.

FIG. 4 is a diagram schematically illustrating a state in which a susceptor cover is placed on a susceptor and a substrate is placed on the susceptor cover.

FIG. 5 is a perspective view schematically illustrating the susceptor cover.

FIG. 6 is an enlarged view schematically illustrating a cross-section of a part of the susceptor cover.

FIG. 7 is an enlarged view schematically illustrating a cross-section of the susceptor cover in which a silicon oxide layer is formed on each of an upper surface and a lower surface thereof.

FIG. 8 is a graph schematically illustrating a relationship between an oxidation process time for silicon carbide (SiC) and a thickness of an oxide layer.

### DETAILED DESCRIPTION

### Embodiments of Present Disclosure

Hereinafter, one or more embodiments (also simply referred to as “embodiments”) of the technique of the present disclosure will be described in detail with reference to the drawings.

(1) Configuration of Substrate Processing Apparatus

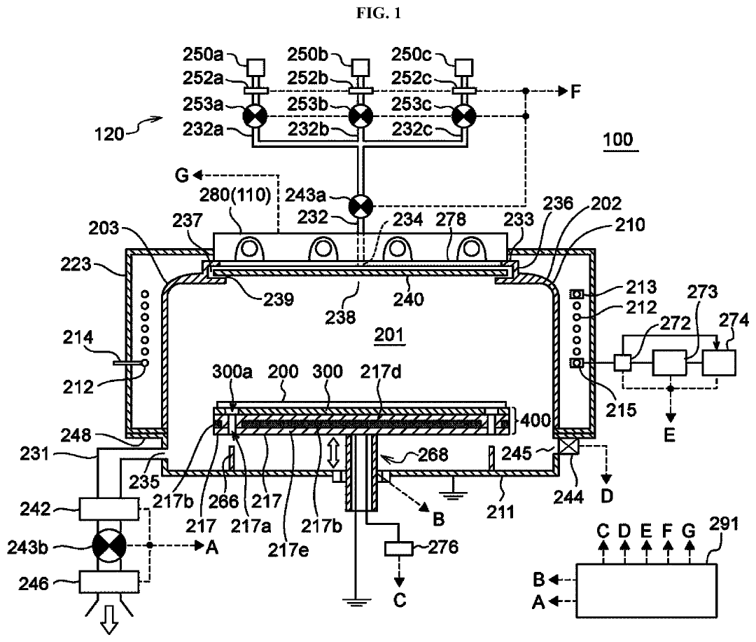

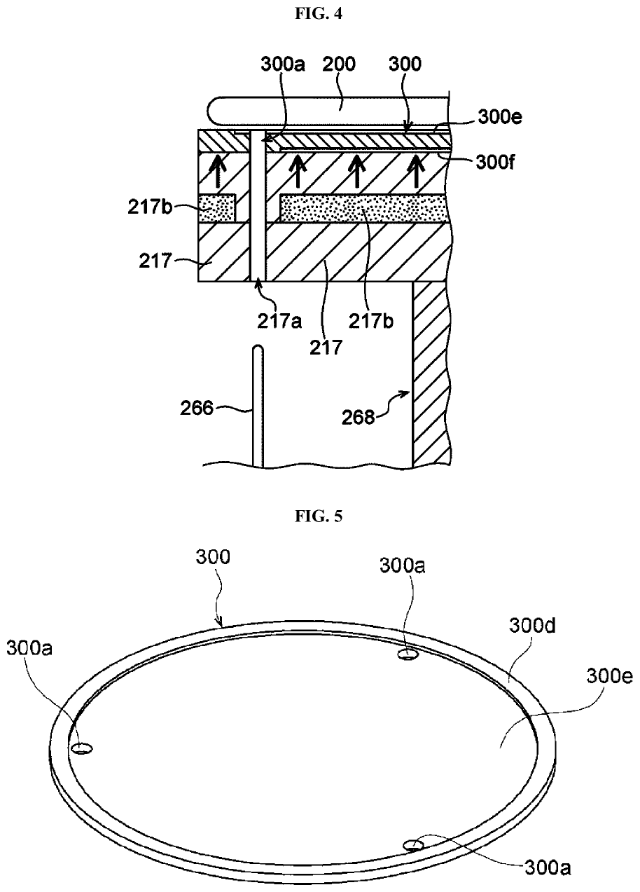

Hereinafter, a configuration of a substrate processing apparatus according to the present embodiments will be described with reference to FIGS. 1, 2 and 4. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

A substrate processing apparatus 100 according to the present embodiments is configured to mainly perform an oxidation process on a film formed on a surface of a substrate 200. The substrate processing apparatus 100 includes a process chamber 201, a susceptor 217 serving as an example of a substrate mounting table, and a susceptor cover 300 serving as an example of a substrate mounting table cover.

<Process Chamber>

The substrate processing apparatus 100 includes a process furnace 202 in which the substrate 200 is processed by a plasma. The process furnace 202 is provided with a process vessel 203 by which the process chamber 201 is defined. The substrate 200 is accommodated in the process chamber 201. The process vessel 203 includes a dome-shaped upper vessel 210 serving as a first vessel and a bowl-shaped lower vessel 211 serving as a second vessel. By covering the lower vessel 211 with the upper vessel 210, the process chamber 201 is defined. The upper vessel 210 is made of a material capable of transmitting an electromagnetic wave, for example, a non-metallic material such as quartz (SiO₂). The lower vessel 211 is made of a metal material. Further, a gate valve 244 is provided on a lower portion of a side wall of the lower vessel 211.

The process chamber 201 includes a plasma generation space around which an electromagnetic field generation electrode 212 constituted by a resonance coil is provided and a substrate processing space that communicates with the plasma generation space and in which the substrate 200 is processed. The plasma generation space refers to a space in which the plasma is generated, for example, a space above a lower end of the electromagnetic field generation electrode 212 and below an upper end of the electromagnetic field generation electrode 212 in the process chamber 201. On the other hand, the substrate processing space refers to a space in which the substrate 200 is processed by using the plasma, for example, a space below the lower end of the electromagnetic field generation electrode 212.

<Susceptor>

The susceptor 217 is provided in the process chamber 201, supports the substrate 200, and is heated by a susceptor heater 217b serving as an example of a heater. The susceptor 217 is also heated by an upper heater 280 serving as an example of the heater. The upper heater 280 is provided above the process chamber 201. The susceptor 217 serving as the substrate mounting table on which the substrate 200 is placed is provided at a center of a bottom portion of the process chamber 201. For example, the susceptor 217 is of a circular shape when viewed from above, and is constituted by an upper surface portion 217d, a lower surface portion 217e and the susceptor heater 217b interposed therebetween. The upper surface portion 217d and the lower surface portion 217e are made of the same material. For example, each of the upper surface portion 217d and the lower surface portion 217e of the susceptor 217 is made of a non-metallic material such as aluminum nitride (AlN), ceramics and quartz.

In the susceptor 217 in the process chamber 201 in which the substrate 200 placed on the susceptor 217 is processed, the susceptor heater 217b serving as a part of a heating structure 110 configured to radiate (or emit) an infrared light so as to heat the substrate 200 accommodated in the process chamber 201 is integrally embedded in the susceptor 217 between the upper surface portion 217d and the lower surface portion 217e. Specifically, the susceptor heater 217b is inserted into a groove provided on a lower surface of the upper surface portion 217d, and is covered with the lower surface portion 217e from a lower side of the susceptor heater 217b. When an electric power is supplied to the susceptor heater 217b, the susceptor heater 217b is configured to be capable of heating the substrate 200 such that the surface of the substrate 200 is heated to a predetermined temperature within a range from 25° C. to 800° C., for example. Further, for example, the susceptor heater 217b is made of a material selected from the group of silicon carbide (SiC), carbon and molybdenum.

The susceptor heater 217b mainly radiates a light whose wavelength is within an infrared light band (about 0.7 μm to 1,000 μm). For example, when the susceptor heater 217b is made of SiC, by supplying an electric current to the susceptor heater 217b, the infrared light whose wavelength is about 1 μm to 20 μm, more preferably about 1 μm to 15 μm is radiated from the susceptor heater 217b. In such a case, for example, a peak wavelength of the infrared light may be around 5 μm. In order to radiate a sufficient amount of the infrared light, it is preferable to elevate a temperature of the susceptor heater 217b to 500° C. or higher, preferably 1,000° C. or higher. Further, in the present specification, a notation of a numerical range such as “1 μm to 20 μm” means that a lower limit and an upper limit are included in the numerical range. Therefore, for example, a numerical range “1 μm to 20 μm” means a range equal to or higher than 1 μm and equal to or less than 20 μm. The same also applies to other numerical ranges described herein.

A susceptor elevator 268 including a driver (which is a driving structure) configured to elevate and lower the susceptor 217 is provided at the susceptor 217. In addition, a plurality of first through-holes including a first through-hole 217a of a circular shape when viewed from above are provided at the susceptor 217, and a plurality of substrate lift pins including a substrate lift pin 266 are provided at a bottom surface of the lower vessel 211 at locations corresponding to the plurality of first through-holes. Hereinafter, the plurality of first through-holes including the first through-hole 217a may also be simply referred to as first through-holes 217a, and the plurality of substrate lift pins including the substrate lift pin 266 may also be simply referred to as substrate lift pins 266.

<Susceptor Cover>

An upper surface of the susceptor 217 is covered with the susceptor cover 300. The susceptor cover 300 is of a circular shape whose size is slightly smaller than that of the susceptor 217 when viewed from above, and is made of a material different from that of the upper surface portion 217d and the lower surface portion 217e of the susceptor 217. For example, the susceptor cover 300 is made of a material such as SiC. Since a thermal conductivity of SiC is high and few impurities are contained in SiC, SiC is suitable as a material for the susceptor cover 300 that contacts the substrate 200 and transfers a heat from the susceptor heater 217b. The susceptor cover 300 is provided with a plurality of second through-holes including a second through-hole 300a and communicating with the first through-holes 217a of the susceptor 217, respectively. Hereinafter, the plurality of second through-holes including the second through-hole 300a may also be simply referred to as second through-holes 300a. Each of the second through-holes 300a is of a circular shape when viewed from above, and an inner diameter of each of the second through-holes 300a is greater than an inner diameter of each of the first through-holes 217a. Further, it is preferable that the susceptor cover 300 is entirely made of SiC in consideration of a uniformity of heat conduction.

For example, at least three of the first through-holes 217a, at least three of the second through-holes 300a and at least three of the substrate lift pins 266 are provided at positions facing one another. When the susceptor 217 is lowered by the susceptor elevator 268, the substrate lift pins 266 pass through the first through-holes 217a and the second through-holes 300a.

The susceptor cover 300 is provided as a separate body with respect to the susceptor 217 and is detachably provided with respect to the susceptor 217.

For example, when the substrate 200 is subjected to the oxidation process and when an apparatus (that is, the substrate processing apparatus 100) is used for a long period of time, not only on the surface of the substrate 200 to be processed but also on a surface of the SiC constituting the susceptor cover 300, silicon (Si) element constituting the SiC and oxygen (O) element contained in an inner atmosphere of the process chamber 201 are bonded, and a silicon oxide layer (also referred to as a “SiO₂ layer”) is formed on a surface of the susceptor cover 300 by a diffusion reaction. An emissivity of the SiO₂ layer is higher than that of the SiC, and the emissivity of the SiO₂ layer increases as a thickness of the oxide layer (that is, the SiO₂ layer) formed on the surface of the SiC increases. As a result, a temperature of the substrate 200 that receives the heat radiation from the surface of the susceptor cover 300 is elevated with an increase in the thickness of the oxide layer, and a processing amount such as a thickness of a film formed on the substrate 200 tends to increase. That is, a processing result for the substrate 200 may fluctuate with a lapse of time of operating the apparatus. In order to reduce such a fluctuation in the processing results, for example, a temperature of the heater may be set high at an initial stage of an operation of the substrate processing apparatus 100, and a pre-set temperature of the heater should be adjusted to be lowered as an operation period of the substrate processing apparatus 100 elapses such that the processing result is constant (for example, the thickness of the film obtained by a process such as the oxidation process is constant). Further, in order to return the susceptor cover 300 to an initial state of the operation of the substrate processing apparatus 100, the susceptor cover 300 should be replaced with a new one, which may increase a replacement cost.

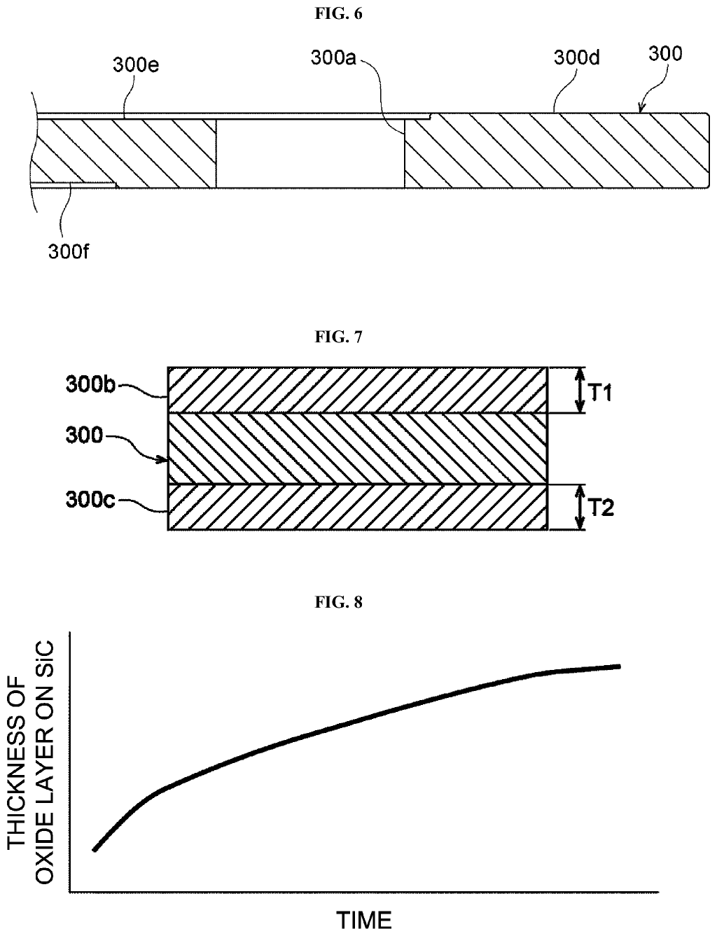

According to the present embodiments, the susceptor cover 300 is arranged on the upper surface of the susceptor 217, and is provided with a silicon oxide layer (also referred to as a “Si oxide layer” or the “SiO₂ layer”) 300b of a first thickness “T1” at least on the surface (that is, an upper surface) of the susceptor cover 300 where the substrate 200 is placed (see FIG. 7). Further, a thickness of a layer such as the silicon oxide layer 300b shown in FIG. 7 is exaggerated. For example, the first thickness T1 is 0.45 μm to 10 μm, preferably 1 μm to 2 μm, and more preferably 1.2 μm to 2 μm. The upper surface of the susceptor cover 300 may also be referred to as a “front surface”, and a lower surface of the susceptor cover 300 may also be referred to as a “back surface”.

The larger the thickness of the Si oxide layer 300b, the lower a rate of increase in the thickness of the Si oxide layer 300b with respect to a processing time of the oxidation process performed in the process chamber 201. Therefore, as the first thickness T1 increases, it is possible to suppress a fluctuation of the emissivity due to a change in the thickness of the oxide layer on the surface of the susceptor cover 300 according to the oxidation process of the substrate 200. Specifically, by forming the Si oxide layer 300b whose thickness is the first thickness T1 of at least 0.45 μm or more, it is possible to obtain a significant effect of reducing the rate of increase in the thickness of the oxide layer. When the first thickness T1 is smaller than 0.45 μm, it may not be possible to obtain the significant effect of reducing the rate of increase in the thickness of the Si oxide layer 300b with respect to a substrate processing time. Further, preferably, by forming the Si oxide layer 300b whose thickness is the first thickness T1 of 1 μm or more, it is possible to surely reduce the rate of increase in the thickness of the oxide layer with respect to the substrate processing time to a practical level. When the first thickness T1 is smaller than 1 μm, in particular, under a condition where a process temperature is 600° C. or higher, it may not be possible to obtain the significant effect of reducing the rate of increase in the thickness of the Si oxide layer 300b with respect to the substrate processing time.

FIG. 8 is a graph schematically illustrating a relationship between an oxidation process time and a thickness of an oxide layer (oxide film) (that is, the film formed by the oxidation process). As described above, in order to surely reduce the rate of increase in the thickness of the oxide layer to a practical level, it is preferable that the first thickness T1 is equal to or greater than a layer thickness at which the graph shows a tendency to saturate. When the thickness of the Si oxide layer 300b is greater than 2 μm, an effect of suppressing an oxidation rate is almost saturated. Therefore, considering a cost and time for forming the Si oxide layer 300b, it is preferable that the thickness of the Si oxide layer 300b is 2 μm or less. Further, when the thickness of the Si oxide layer 300b is greater than 10 μm, it becomes difficult to form the Si oxide layer 300b in a practical time. Therefore, it is preferable that the thickness of the Si oxide layer 300b is 10 μm or less.

The Si oxide layer 300b is formed on at least an entirety (entire surface) of a portion (of the upper surface of the susceptor cover 300) facing the substrate 200. Further, more preferably, the Si oxide layer 300b is formed on an entirety of the upper surface of the susceptor cover 300 (that is, the entirety of the upper surface (of the susceptor cover 300) including a portion without facing the substrate 200). Thereby, it is suitable to uniformly transfer the radiated heat from the susceptor cover 300 to the substrate 200 in a direction of a substrate surface (that is, the surface of the substrate 200). Further, the Si oxide layer 300b is formed such that the thickness of the Si oxide layer 300b is uniform in the direction of the substrate surface. Since an emissivity distribution may become non-uniform on the surface of the susceptor cover 300 due to a non-uniform thickness of the Si oxide layer 300b, the first thickness T1 is preferably uniform over at least the entirety of the portion (of the upper surface of the susceptor cover 300) facing the substrate 200, and more preferably over the entirety of the upper surface of the susceptor cover 300.

Further, the susceptor cover 300 is provided with a silicon oxide layer (also referred to as a “Si oxide layer” or the “SiO₂ layer”) 300c not only on the surface (upper surface) of the susceptor cover 300 where the substrate 200 is placed but also on a surface (that is, the lower surface) of the susceptor cover 300 facing the susceptor 217. Thereby, even when the Si oxide layer increases due to an oxidation reaction on the lower surface of the susceptor cover 300 according to the oxidation process of the substrate 200, it is possible to reduce the rate of increase in the thickness of the oxide layer as in a case of reducing the rate of increase in the thickness of the oxide layer on the upper surface of the susceptor cover 300. Therefore, according to the present embodiments, even when the Si oxide layer increases due to the oxidation reaction on the lower surface of the susceptor cover 300 according to the oxidation process of the substrate 200, it is possible to suppress the fluctuation of the emissivity due to the change in the thickness of the Si oxide layer on the surface of the susceptor cover 300 according to the oxidation process of the substrate 200.

Specifically, the susceptor cover 300 includes the Si oxide layer 300c of a second thickness of “T2” on the surface (lower surface) of the susceptor cover 300 facing the susceptor 217 (see FIG. 7). Thereby, it is possible to reduce an influence of a change in the emissivity on the lower surface of the susceptor cover 300. For example, the second thickness T2 is 0.45 μm to 10 μm, preferably 1 μm to 2 μm, and more preferably 1.2 μm to 2 μm. By forming the Si oxide layer 300c whose thickness is the second thickness T2 of at least 0.45 μm or more, it is possible to obtain the significant effect of reducing the rate of increase in the thickness of the oxide layer. When the second thickness T2 is smaller than 0.45 μm, it may not be possible to obtain the significant effect of reducing the rate of increase in the thickness of the Si oxide layer 300c with respect to the substrate processing time. Further, preferably, by forming the Si oxide layer 300c whose thickness is the second thickness T2 of 1 μm or more, it is possible to surely reduce the rate of increase in the thickness of the oxide layer with respect to the substrate processing time to the practical level. When the second thickness T2 is smaller than 1 μm, in particular, under the condition where the process temperature is 600° C. or higher, it may not be possible to obtain the significant effect of reducing the rate of increase in the thickness of the Si oxide layer 300c with respect to the substrate processing time. Further, in order to surely reduce the rate of increase in the thickness of the oxide layer to the practical level, it is preferable that the second thickness T2 is equal to or greater than the layer thickness at which the graph (see FIG. 8) shows the tendency to saturate. When the thickness of the Si oxide layer 300c is greater than 2 μm, the effect of suppressing the oxidation rate is almost saturated. Therefore, considering the cost and time for forming the Si oxide layer 300c, it is preferable that the thickness of the Si oxide layer 300c is 2 m or less. Further, when the thickness of the Si oxide layer 300c is greater than 10 μm, it becomes difficult to form the Si oxide layer 300c in a practical time. Therefore, it is preferable that the thickness of the Si oxide layer 300c is 10 μm or less.

When an oxygen-containing gas is used for the substrate processing, the upper surface of the susceptor cover 300 (which is easily exposed to the oxygen-containing gas) is more likely to be oxidized during the substrate processing. Therefore, it is preferable that the first thickness T1 is greater than the second thickness T2. On the other hand, depending on the conditions such as a difference in gas types used in the substrate processing and a difference in the operation of the substrate processing apparatus 100, the lower surface of the susceptor cover 300 may be more easily oxidized by the susceptor heater 217b. In such a case, it is preferable that the second thickness T2 is greater than the first thickness T1. When an oxide layer forming process is simultaneously performed on both upper and lower surfaces of the susceptor cover 300, the first thickness T1 and the second thickness T2 may be the same.

Further, the upper surface portion 217d of the susceptor 217 may be made of a material capable of transmitting an infrared component of a radiated light emitted from the susceptor heater 217b. As such a material, for example, transparent quartz may be used. In such a case, a ratio of the susceptor cover 300 being heated by the radiated heat is greater than that in a case where the susceptor 217 is made of an opaque material that does not transmit the infrared component of the radiated light emitted from the susceptor heater 217b. Therefore, the susceptor cover 300 according to the present disclosure capable of suppressing a change (fluctuation) of the emissivity with a lapse of time can be more preferably used when the susceptor 217 (more specifically, the upper surface portion 217d) is made of a material capable of transmitting the infrared component of the radiated light emitted from the heater (that is, the susceptor heater 217b).

The Si oxide layers 300b and 300c may be formed by, for example, the following method using the present apparatus (that is, the substrate processing apparatus 100) or a heating apparatus different from the present apparatus.
After transferring (or loading) the susceptor cover 300 into the process chamber 201, an oxidation gas is supplied to the process chamber 201. When supplying the oxidation gas, it is preferable to arrange the susceptor cover 300 such that both the upper surface and the lower surface of the susceptor cover 300 are evenly exposed to the oxidation gas and such that each of the Si oxide layers 300b and 300c is formed with a uniform thickness on the upper surface and the lower surface of the susceptor cover 300, respectively.
While continuously supplying the oxidation gas, the susceptor cover 300 is heated by the heater such as the susceptor heater 217b. In order to shorten a period of forming the Si oxide layers 300b and 300c, for example, it is preferable to heat the susceptor cover 300 at a temperature higher than that of the susceptor cover 300 during the substrate processing.

Further, as the oxidation gas, for example, a gas such as oxygen (O₂) gas, nitrous oxide (N₂O) gas, nitrogen monoxide (NO) gas, nitrogen dioxide (NO₂) gas, ozone (O₃) gas, water vapor (H₂O gas), carbon monoxide (CO) gas and carbon dioxide (CO₂) gas may be used. As the oxidation gas, one or more of the gases described above may be used. Further, an air atmosphere may be used as the oxidation gas.

By using the method described above, it is possible to uniformly form the Si oxide layer (that is, each of the Si oxide layers 300b and 300c) of a thickness of 1 μm or more on the surface of the susceptor cover 300 along a direction of a substrate placing surface of the susceptor cover 300. The Si oxide layer formed on the surface of the susceptor cover 300 by performing the oxidation process with the substrate 200 placed on the susceptor cover 300 may be non-uniformly formed on the substrate placing surface of the susceptor cover 300 along the direction of the substrate placing surface of the susceptor cover 300 depending on the influence of the substrate 200 placed on the substrate placing surface and the contents of the oxidation process. Therefore, it is preferable that the Si oxide layer formed on the surface of the susceptor cover 300 is formed by oxidizing the surface of the susceptor cover 300 without placing the substrate 200 on the susceptor cover 300 as in the method described above.

As shown in FIGS. 5 and 6, a substrate support 300d of a first height D1 is formed on the surface (upper surface) of the susceptor cover 300 where the substrate 200 is placed. The substrate support 300d is configured such that a gap of the first height D1 can be provided between the susceptor cover 300 and the substrate 200 by the substrate support 300d. For example, the first height D1 is 0.1 mm to 5 mm, and may set to be 1 mm. The substrate support 300d is formed at a location radially outward from a position of the second through-hole 300a, and extends along an outer periphery of the susceptor cover 300, for example. An inner portion in a radial direction from the substrate support 300d is configured as a recess (which is a concave structure) 300e with respect to the substrate support 300d.

As a result, when the substrate 200 is placed on the upper surface of the susceptor cover 300, a gap is provided between the substrate 200 and the recess 300e. When a gap space is provided on the upper surface of the susceptor cover 300 as described above, since the upper surface of the susceptor cover 300 is exposed to the oxidation gas existing in the gap space during the substrate processing, it is possible to easily proceed with an oxidation on the upper surface of the susceptor cover 300. Therefore, by forming the Si oxide layer 300b on the upper surface of the susceptor cover 300 in advance, it is possible to more effectively suppress the oxidation as compared with a case where the gap space is not provided. Further, by providing the gap space, a ratio of the heat radiation from the susceptor cover 300 to the substrate 200 is greater than that of the heat conduction caused by a direct contact between the susceptor cover 300 and the substrate 200. Therefore, by forming the Si oxide layer 300b on the upper surface of the susceptor cover 300 in advance, it is possible to more effectively suppress a change in the heat radiation with a lapse of time.

Further, by providing a gap of a predetermined height in advance between a back surface of the substrate 200 and the upper surface of the susceptor cover 300, even when the substrate 200 is distorted or the upper surface of the susceptor cover 300 is distorted, it is possible to uniformly transfer the heat from the susceptor heater 217b to the substrate 200 in the direction of the substrate surface through a gap space between the back surface of the substrate 200 and the upper surface of the susceptor cover 300.

When the substrate 200 is placed on the substrate support 300d, for example, a substance such as foreign matters adhering to an upper surface of the substrate support 300d may adhere to the back surface of the substrate 200. Further, for example, the substrate 200 may slip sideways when a gaseous substance is interposed between the substrate 200 and the substrate support 300d. By providing the substrate support 300d such that the gap (that is, the recess 300e) of a predetermined height is provided on the back surface of the substrate 200, it is possible to suppress an adhesion of the foreign matters to the back surface of the substrate 200 and a sideslip of the substrate 200.

Further, a recess 300f of a second height D2 is formed on the surface (lower surface) of the susceptor cover 300 facing the susceptor 217. The recess 300f is configured such that a gap of the second height D2 can be provided between the susceptor 217 and the susceptor cover 300. For example, the second height D2 is 0.1 mm to 5 mm, and may set to bel mm. The recess 300f is formed in the radial direction of the susceptor cover 300, for example, at a location radially inward of the position of the second through-hole 300a.

As a result, when the susceptor cover 300 is placed on the susceptor 217, the gap is provided between the susceptor cover 300 and the susceptor 217. When the gap space is provided on the lower surface of the susceptor cover 300 as described above, since the lower surface of the susceptor cover 300 is exposed to the oxidation gas existing in the gap space during the substrate processing, it is possible to easily proceed with the oxidation on the lower surface of the susceptor cover 300. Therefore, by forming the Si oxide layer 300c on the lower surface of the susceptor cover 300 in advance, it is possible to more effectively suppress the oxidation as compared with a case where the gap space is not provided. Further, by providing the gap space, a ratio of the heat radiation from the susceptor 217 to the susceptor cover 300 is greater than that of the heat conduction caused by a direct contact between the susceptor 217 and the susceptor cover 300. Therefore, by forming the Si oxide layer 300c on the lower surface of the susceptor cover 300 in advance, it is possible to more effectively suppress the change in the heat radiation with a lapse of time.

Further, by providing a gap of a predetermined height in advance between the susceptor cover 300 and the susceptor 217 with the susceptor heater 217b embedded therein, even when the upper surface of the susceptor cover 300 or the susceptor 217 is distorted or the surface of the susceptor cover 300 or the susceptor 217 is non-uniform, it is possible to uniformly transfer the heat from the susceptor heater 217b to the susceptor cover 300 in the direction of the substrate surface through a gap space between the susceptor cover 300 and the susceptor 217.

According to the present embodiments, it is possible to suppress the change of the emissivity of the susceptor cover 300 with the lapse of the operation period of the apparatus and suppress a change in the temperature of the substrate 200. Thereby, it is possible to reduce a change in a thickness of the oxide layer formed on the surface of the substrate 200 (that is, a change in a substrate processing result) caused by a long term operation of the substrate processing apparatus 100. Further, it is possible to reduce the number of times of performing a temperature adjustment such that the thickness of the oxide layer formed on the substrate 200 becomes uniform. Furthermore, it is possible to reduce a frequency of replacing the susceptor cover 300 made of silicon carbide with a new one.

<Process Gas Supplier>

A process gas supplier (which is a process gas supply structure or a process gas supply system) 120 configured to supply a process gas into the process vessel 203 is configured as follows.

A gas supply head 236 is provided above the process chamber 201, that is, on an upper portion of the upper vessel 210. The gas supply head 236 includes a cap-shaped lid 233, a gas inlet port 234, a buffer chamber 237, an opening 238, a shield plate 240 and a gas outlet port 239. The gas supply head 236 is configured to supply the process gas such as a reactive gas into the process chamber 201.

An oxygen-containing gas supply pipe 232a through which the oxygen gas serving as the oxygen-containing gas is supplied, a hydrogen-containing gas supply pipe 232b through which a hydrogen-containing gas is supplied and an inert gas supply pipe 232c through which an inert gas is supplied are connected to join the gas inlet port 234. An oxygen-containing gas supply source 250a, a mass flow controller (MFC) 252a serving as a flow rate controller and a valve 253a serving as an opening/closing valve are provided at the oxygen-containing gas supply pipe 232a. A hydrogen-containing gas supply source 250b, an MFC 252b and a valve 253b are provided at the hydrogen-containing gas supply pipe 232b. An inert gas supply source 250c, an MFC 252c and a valve 253c are provided at the inert gas supply pipe 232c. A valve 243a is provided on a downstream side of a gas supply pipe 232 at a location where the oxygen-containing gas supply pipe 232a, the hydrogen-containing gas supply pipe 232b and the inert gas supply pipe 232c join. The valve 243a is connected to the gas inlet port 234.

The process gas supplier (which is a gas supply structure) 120 according to the present embodiments is constituted mainly by the gas supply head 236, the oxygen-containing gas supply pipe 232a, the hydrogen-containing gas supply pipe 232b, the inert gas supply pipe 232c, the MFCs 252a, 252b and 252c, the valves 253a, 253b, 253c and 243a.

<Exhauster>

A gas exhaust port 235 through which the inner atmosphere of the process chamber 201 is exhausted is provided on the side wall of the lower vessel 211. An upstream end of a gas exhaust pipe 231 is connected to the gas exhaust port 235. An APC (Automatic Pressure Controller) 242 serving as a pressure regulator (which is a pressure adjusting structure), a valve 243b serving as an opening/closing valve and a vacuum pump 246 serving as a vacuum exhaust apparatus are provided at the gas exhaust pipe 231.

An exhauster (which is an exhaust structure or an exhaust system) according to the present embodiments is constituted mainly by the gas exhaust port 235, the gas exhaust pipe 231, the APC 242 and the valve 243b. The exhauster may further include the vacuum pump 246.

<Plasma Generator>

The electromagnetic field generation electrode 212 constituted by the resonance coil of a helical shape is provided around an outer periphery of the process chamber 201 so as to surround the process chamber 201, that is, around an outer portion of a side wall of the upper vessel 210. An RF (Radio Frequency) sensor 272, a high frequency power supply 273 and a matcher 274 configured to perform an impedance matching or an output frequency matching for the high frequency power supply 273 are connected to the electromagnetic field generation electrode 212. The electromagnetic field generation electrode 212 extends along an outer peripheral surface of the process vessel 203 while spaced apart from the outer peripheral surface of the process vessel 203, and is configured to generate an electromagnetic field in the process vessel 203 when a high frequency power (RF power) is supplied to the electromagnetic field generation electrode 212. That is, the electromagnetic field generation electrode 212 according to the present embodiments may be constituted by an inductively coupled plasma (ICP) type electrode.

The high frequency power supply 273 is configured to supply the RF power to the electromagnetic field generation electrode 212. The RF sensor 272 is provided at an output side of the high frequency power supply 273. The RF sensor 272 is configured to monitor information of the traveling wave or reflected wave of the supplied high frequency power. The reflected wave of the RF power monitored by the RF sensor 272 is input to the matcher 274, and the matcher 274 is configured to adjust an impedance of the high frequency power supply 273 or a frequency of the RF power output from the high frequency power supply 273 so as to minimize the reflected wave based on the information of the reflected wave inputted from the RF sensor 272.

A winding diameter, a winding pitch and the number of winding turns of the resonance coil serving as the electromagnetic field generation electrode 212 are set such that the electromagnetic field generation electrode 212 resonates at a constant wavelength to form a standing wave of a predetermined wavelength. That is, an electrical length of the resonance coil is set to an integral multiple of a wavelength of a predetermined frequency of the high frequency power supplied from the high frequency power supply 273.

Both ends of the resonance coil serving as the electromagnetic field generation electrode 212 are electrically grounded. At least one end of the resonance coil is grounded via a movable tap 213, and the other end of the resonance coil is grounded via a fixed ground 214. In addition, in order to fine-tune the impedance of the resonance coil, a power feeder (not shown) is constituted by a movable tap 215 between the grounded ends of the resonance coil.

A shield plate 223 is provided as a shield against the electric field outside the resonance coil serving as the electromagnetic field generation electrode 212.

<Controller>

A controller 291 serving as a control structure is configured to control the APC 242, the valve 243b and the vacuum pump 246 through a signal line “A”, the susceptor elevator 268 through a signal line “B”, a heater power regulator 276 through a signal line “C”, the gate valve 244 through a signal line “D”, the RF sensor 272, the high frequency power supply 273 and the matcher 274 through a signal line “E”, and the MFCs 252a, 252b and 252c and the valves 253a, 253b, 253c and 243a through a signal line “F”.

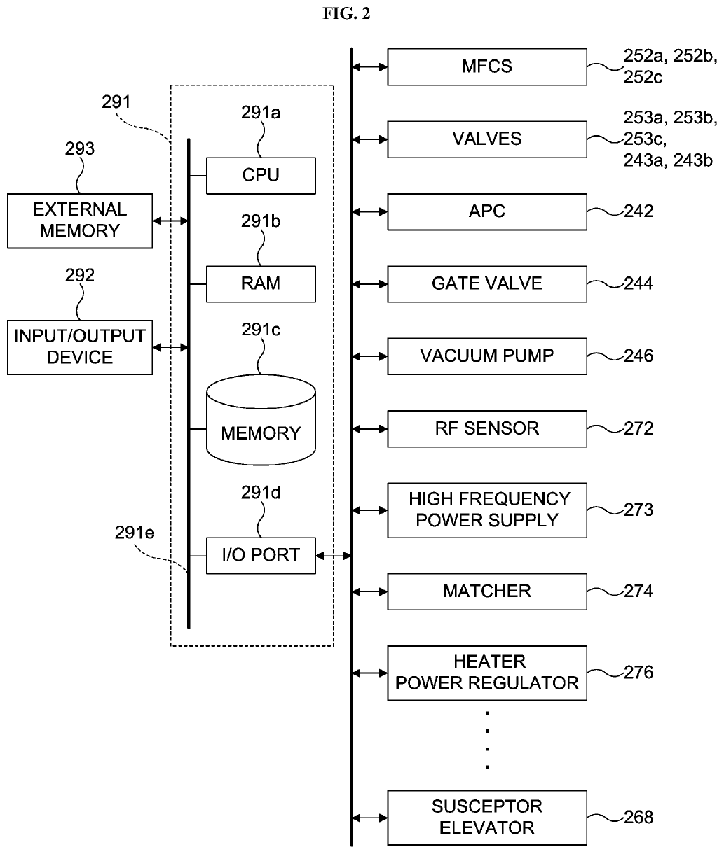

As shown in FIG. 2, the controller 291 serving as a control structure (control apparatus) is constituted by a computer including a CPU (Central Processing Unit) 291a, a RAM (Random Access Memory) 291b, a memory 291c and an I/O port 291d. The RAM 291b, the memory 291c and the I/O port 291d may exchange data with the CPU 291a through an internal bus 291e. For example, an input/output device 292 constituted by components such as a touch panel and a display may be connected to the controller 291.

The memory 291c may be embodied by a component such as a flash memory and a hard disk drive (HDD). For example, a control program configured to control the operation of the substrate processing apparatus 100 and a process recipe in which information such as sequences and conditions of a substrate processing described later is stored may be readably stored in the memory 291c. The process recipe is obtained by combining steps of the substrate processing described later such that the controller 291 can execute the steps to acquire a predetermined result, and functions as a program. Hereinafter, the process recipe and the control program may be collectively or individually referred to as a “program”.

The I/O port 291d is electrically connected to the above-described components such as the MFCs 252a, 252b and 252c, the valves 253a, 253b, 253c, 243a and 243b, the gate valve 244, the APC 242, the vacuum pump 246, the RF sensor 272, the high frequency power supply 273, the matcher 274, the susceptor elevator 268 and the heater power regulator 276.

The CPU 291a is configured to read and execute the control program stored in the memory 291c, and to read the process recipe stored in the memory 291c in accordance with an instruction such as an operation command inputted via the input/output device 292. For example, the CPU 291a may be configured to be capable of performing the operation, in accordance with the contents of the read process recipe, such as an operation of adjusting an opening degree of the APC 242, an opening and closing operation of the valve 243b and a start and stop of the vacuum pump 246 via the I/O port 291d and the signal line “A”, an elevating and lowering operation of the susceptor elevator 268 via the I/O port 291d and the signal line “B”, a power supply amount adjusting operation (temperature adjusting operation) to the susceptor heater 217b by the heater power regulator 276 via the I/O port 291d and the signal line “C”, an opening and closing operation of the gate valve 244 via the I/O port 291d and the signal line “D”, a controlling operation of the RF sensor 272, the matcher 274 and the high frequency power supply 273 via the I/O port 291d and the signal line “E”, flow rate adjusting operations for various gases by the MFCs 252a, 252b and 252c and opening and closing operations of the valves 253a, 253b, 253c and 243a via the I/O port 291d and the signal line “F”, and a power supply amount adjusting operation (temperature adjusting operation) to the upper heater 280 by the heater power regulator 276 via the I/O port 291d and a signal line “G”.

The controller 291 may be embodied by installing the above-described program stored in an external memory 293 into a computer. The memory 291c or the external memory 293 may be embodied by a non-transitory computer readable recording medium. Hereinafter, the memory 291c and the external memory 293 may be collectively or individually referred to as a “recording medium”.

(2) Substrate Processing

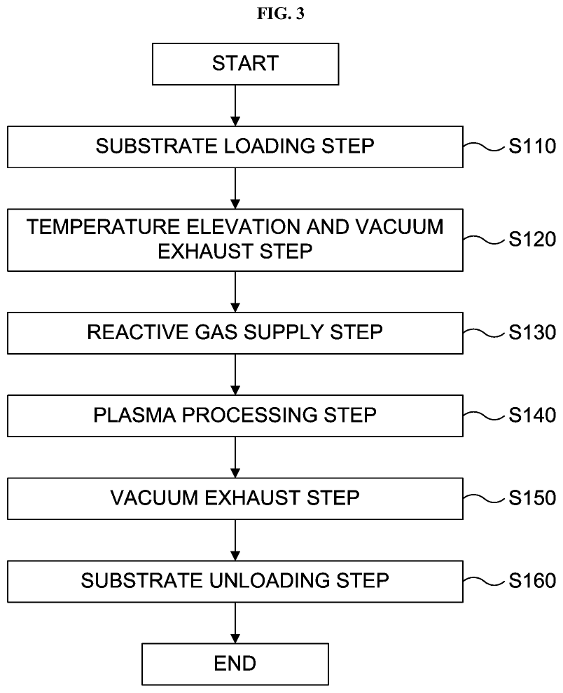

Subsequently, the substrate processing according to the present embodiments will be described mainly with reference to FIG. 3. FIG. 3 is a flow chart schematically illustrating the substrate processing according to the present embodiments. The substrate processing according to the present embodiments, which is a part of a manufacturing process of a semiconductor device (a method of manufacturing a semiconductor device) such as a flash memory, is performed by using the substrate processing apparatus 100 described above. In the following description, operations of components constituting the substrate processing apparatus 100 are controlled by the controller 291.

In addition, a silicon layer is formed in advance on the surface of the substrate 200 to be processed in the substrate processing according to the present embodiments. In the present embodiments, for example, the oxidation process serving as a process using the plasma is performed on the silicon layer.

<Substrate Loading Step S110>

First, the susceptor 217 is lowered to a position of transferring the substrate 200 by the susceptor elevator 268 such that the substrate lift pins 266 pass through the first through-holes 217a of the susceptor 217 and the second through-holes 300a of the susceptor cover 300. Subsequently, the gate valve 244 is opened, and the substrate 200 is transferred (loaded) into the process chamber 201 by using a substrate transfer device (not shown) from a vacuum transfer chamber (not shown) provided adjacent to the process chamber 201. The substrate 200 loaded into the process chamber 201 is supported in a horizontal orientation by the substrate lift pins 266 protruding from the surface of the susceptor cover 300. Thereafter, the susceptor elevator 268 elevates the susceptor 217 until the substrate 200 is placed on and supported by the upper surface of the susceptor cover 300.

<Temperature Elevation and Vacuum Exhaust Step S120>

Subsequently, the temperature of the substrate 200 loaded into the process chamber 201 is elevated. In the step S120, the susceptor heater 217b is heated in advance, for example, to a predetermined temperature within a range of 500° C. to 1,000° C., and the substrate 200 placed on the susceptor 217 (that is, on the susceptor cover 300) is heated to the predetermined temperature by the heat generated by the susceptor heater 217b. In the step S120, for example, the substrate 200 is heated such that the temperature of the substrate 200 reaches and is maintained at 700° C. Further, while the substrate 200 is being heated, the vacuum pump 246 vacuum-exhausts the inner atmosphere of the process chamber 201 through the gas exhaust pipe 231 such that an inner pressure of the process chamber 201 reaches and is maintained at a predetermined pressure. The vacuum pump 246 is continuously operated at least until a substrate unloading step S160 described later is completed.

<Reactive Gas Supply Step S130>

Subsequently, as a supply of the reactive gas, a supply of the oxygen-containing gas and a supply of the hydrogen-containing gas are started. Specifically, the valves 253a and 253b are opened, and the supply of the oxygen-containing gas and the supply of the hydrogen-containing gas into the process chamber 201 are started while flow rates of the oxygen-containing gas and the hydrogen-containing gas are adjusted by the MFCs 252a and 252b, respectively.

Further, the inner atmosphere of the process chamber 201 is exhausted by adjusting the opening degree of the APC 242 such that the inner pressure of the process chamber 201 reaches and is maintained at a predetermined pressure. The oxygen-containing gas and the hydrogen-containing gas are continuously supplied into the process chamber 201 while the inner atmosphere of the process chamber 201 is appropriately exhausted until a plasma processing step S140 described later is completed.

As the oxygen-containing gas, for example, a gas such as oxygen (O₂) gas, nitrous oxide (N₂O) gas, nitrogen monoxide (NO) gas, nitrogen dioxide (NO₂) gas, ozone (O₃) gas, water vapor (H₂O gas), carbon monoxide (CO) gas and carbon dioxide (CO₂) gas may be used. As the oxygen-containing gas, one or more of the gases described above may be used.

Further, as the hydrogen-containing gas, for example, a gas such as hydrogen (H₂) gas, deuterium (D₂) gas, H₂O gas and ammonia (NH₃) gas may be used. As the hydrogen-containing gas, one or more of the gases described above may be used.

<Plasma Processing Step S140>

When the inner pressure of the process chamber 201 is stabilized, the high frequency power is supplied to the electromagnetic field generation electrode 212 from the high frequency power supply 273. Thereby, a high frequency electric field is formed in the plasma generation space to which the oxygen-containing gas and the hydrogen-containing gas are supplied, and the donut-shaped induction plasma whose plasma density is the highest is excited by the high frequency electric field at a height corresponding to the electric midpoint of the electromagnetic field generation electrode 212 in the plasma generation space. The process gas containing the oxygen-containing gas in a plasma state and the hydrogen-containing gas in a plasma state is plasma-excited and dissociates. As a result, reactive species such as oxygen radicals containing oxygen (oxygen active species), oxygen ions, hydrogen radicals containing hydrogen (hydrogen active species) and hydrogen ions may be generated.

The radicals generated by the induction plasma and non-accelerated ions are uniformly supplied onto the surface of the substrate 200 placed on the susceptor 217 in the substrate processing space. Then, the radicals and the ions uniformly supplied onto the surface of the substrate 200 uniformly react with the silicon layer formed on the surface of the substrate 200. Thereby, the silicon layer is modified into a silicon oxide layer whose step coverage is good.

After a predetermined process time has elapsed (for example, 10 seconds to 1,000 seconds), the supply of the high frequency power from the high frequency power supply 273 is stopped to stop a plasma discharge in the process chamber 201. In addition, the valves 253a and 253b are closed to stop the supply of the oxygen-containing gas and the supply of the hydrogen-containing gas into the process chamber 201. Thereby, the plasma processing step S140 is completed.

<Vacuum Exhaust Step S150>

After the supply of the oxygen-containing gas and the supply of the hydrogen-containing gas are stopped, the inner atmosphere of the process chamber 201 is vacuum-exhausted through the gas exhaust pipe 231. Thereby, the gas in the process chamber 201 is exhausted outside of the process chamber 201. Thereafter, the opening degree of the APC 242 is adjusted such that the inner pressure of the process chamber 201 is adjusted to the same pressure as that of the vacuum transfer chamber (not shown) provided adjacent to the process chamber 201.

<Substrate Unloading Step S160>

After the inner pressure of the process chamber 201 is adjusted to a predetermined pressure, the susceptor 217 is lowered to the position of transferring the substrate 200 until the substrate 200 is supported by the substrate lift pins 266. Then, the gate valve 244 is opened, and the substrate 200 is transferred (unloaded) out of the process chamber 201 by using the substrate transfer device (not shown). Thereby, the substrate processing according to the present embodiments is completed.

As described above, the method of manufacturing the semiconductor device according to the present embodiments is the method of manufacturing the semiconductor device by using the substrate processing apparatus 100, and includes a step of placing the substrate 200 on the susceptor cover 300; a step of heating the substrate 200 by the susceptor heater 217b; and a step of forming the oxide film on the substrate 200 by supplying the oxygen-containing gas to the substrate 200.

<Supplement for Susceptor and Susceptor Cover>

The susceptor heater 217b itself is arranged inside the susceptor 217 constituted by two components (that is, the upper surface portion 217d and the lower surface portion 217e). Therefore, the substrate 200 is heated by the heat conduction and the heat radiation via the susceptor 217. However, when the susceptor 217 is constituted by one component (for example, the lower surface portion 217e alone), the susceptor heater 217b may be provided at the susceptor 217 so as to be in contact with the lower surface of the susceptor 217. Also in such a case, the substrate 200 is heated by the heat conduction and the heat radiation via the susceptor 217. In both cases described above, the susceptor heater 217b is provided at a location where the direct radiation from the susceptor heater 217b can be incident onto at least one of the susceptor cover 300 or the substrate 200 through the susceptor 217.

### Other Embodiments

While the technique of the present disclosure is described in detail by way of the embodiments described above, the technique of the present disclosure is not limited thereto. The technique of the present disclosure may be modified in various ways without departing from the scope thereof.

The above-described embodiments are described by way of an example in which the film formed on the substrate is subjected to the oxidation process using the plasma of the reactive gas containing oxygen. However, the technique according to the present disclosure is not limited thereto, and may also be preferably applied to a process in which the surface of the susceptor cover is oxidized during the substrate processing of the substrate placed on the susceptor cover made of SiC. For example, the susceptor cover according to the technique of the present disclosure may be used when a process of depositing a film on the surface of the substrate placed on the susceptor cover by using an oxidizing agent is performed, or a process of etching a film formed on the surface of the substrate with a gas containing an oxidizing agent is performed.

The entire contents of Japanese Patent Application No. 2020-55165, filed on Mar. 25, 2020, are hereby incorporated in the present specification by reference. All documents, patent applications, and technical standards described herein are hereby incorporated in the present specification by reference to the same extent that the contents of each of the documents, the patent applications and the technical standards are specifically described.

According to some embodiments of the present disclosure, it is possible to suppress the fluctuation in the substrate processing result due to the surface oxidation of the component in the process chamber accompanying the operation of the substrate processing apparatus.

What is claimed is:

1. A substrate processing apparatus comprising:
a process chamber in which a substrate is accommodated;
a substrate mounting table provided in the process chamber and heated by a heater; and
a substrate mounting table cover arranged on an upper surface of the substrate mounting table and configured such that the substrate is placed on an upper surface of the substrate mounting table cover,
wherein the substrate mounting table cover is made of silicon carbide and is provided with a silicon oxide layer of a first thickness at least on the upper surface of the substrate mounting table cover where the substrate is placed.

2. The substrate processing apparatus of claim 1, wherein the heater is provided in the substrate mounting table.

3. The substrate processing apparatus of claim 1, wherein the silicon oxide layer is formed on at least an entire surface of a portion of the upper surface of the substrate mounting table cover where the substrate is placed, and
wherein the portion faces the substrate.

4. The substrate processing apparatus of claim 3, wherein the silicon oxide layer is formed on an entirety of the upper surface of the substrate mounting table cover where the substrate is placed.

5. The substrate processing apparatus of claim 3, wherein the silicon oxide layer is formed with a uniform thickness on the upper surface of the substrate mounting table cover where the substrate is placed.

6. The substrate processing apparatus of claim 4, wherein the silicon oxide layer is formed with a uniform thickness on the upper surface of the substrate mounting table cover where the substrate is placed.

7. The substrate processing apparatus of claim 1, wherein the first thickness is equal to or greater than 1 μm.

8. The substrate processing apparatus of claim 1, wherein the substrate mounting table cover is further provided with a silicon oxide layer of a second thickness on a surface of the substrate mounting table cover facing the upper surface of the substrate mounting table.

9. The substrate processing apparatus of claim 8, wherein the first thickness is greater than the second thickness.

10. The substrate processing apparatus of claim 8, wherein the second thickness is greater than the first thickness.

11. The substrate processing apparatus of claim 1, wherein the substrate mounting table is made of a material capable of transmitting an infrared component of a radiated light emitted from the heater.

12. The substrate processing apparatus of claim 11, wherein the substrate mounting table is made of transparent quartz.

13. The substrate processing apparatus of claim 1, wherein a substrate support configured to support the substrate on an upper surface of the substrate support is provided on the upper surface of the substrate mounting table cover where the substrate is placed such that a gap of a first height is provided between a back surface of the substrate and at least a part of the upper surface of the substrate mounting table cover.

14. The substrate processing apparatus of claim 1, wherein a recess is provided on a surface of the substrate mounting table cover facing the upper surface of the substrate mounting table such that a gap of a second height is provided between the upper surface of the substrate mounting table and at least a part of a surface of the substrate mounting table cover facing the upper surface of the substrate mounting table.

15. The substrate processing apparatus of claim 1, wherein the substrate mounting table cover is detachably provided with respect to the substrate mounting table.

16. The substrate processing apparatus of claim 1, further comprising:
a gas supplier through which an oxygen-containing gas is supplied into the process chamber; and
a controller configured to be capable of controlling the gas supplier so as to supply the oxygen-containing gas into the process chamber with the substrate placed on the substrate mounting table cover.

17. A substrate mounting table cover arranged on an upper surface of a substrate mounting table and configured such that a substrate is placed on an upper surface of the substrate mounting table cover,
wherein the substrate mounting table is provided in a process chamber and heated by a heater, and
wherein the substrate mounting table cover is made of silicon carbide and is provided with a silicon oxide layer of a predetermined first thickness at least on the upper surface of the substrate mounting table cover where the substrate is placed.

18. A method of manufacturing a semiconductor device, comprising:
(a) placing a substrate on a substrate mounting table cover arranged on an upper surface of a substrate mounting table and configured such that the substrate is placed on an upper surface of the substrate mounting table cover, wherein the substrate mounting table is provided in a process chamber and heated by a heater;
(b) heating the substrate placed on the substrate mounting table cover by the heater; and
(c) forming an oxide layer on the substrate by supplying an oxygen-containing gas to the substrate,
wherein the substrate mounting table cover is made of silicon carbide and is provided with a silicon oxide layer of a predetermined first thickness at least on the upper surface of the substrate mounting table cover where the substrate is placed.

19. A non-transitory computer-readable recording medium storing a program that causes, by a computer, a substrate processing apparatus to perform the method of manufacturing a semiconductor device of claim 18.
